(19) United States
(12) Patent Application Publication
(10) Pub. No.: US 2026/0101527 A1
(43) Pub. Date: Apr. 9, 2026

(54) SEMICONDUCTOR DEVICE, MATCHING CIRCUIT, AND FILTER CIRCUIT

(71) Applicant: Murata Manufacturing Co., Ltd., Nagaokakyo (JP)

(72) Inventor: Korekiyo ITO, Nagaokakyo-shi (JP)

(21) Appl. No.: 19/406,145

(22) Filed: Dec. 2, 2025

Related U.S. Application Data
(63) Continuation of application No. PCT/JP2024/017593, filed on May 15, 2024.

(30) Foreign Application Priority Data
Jun. 7, 2023 (JP) 2023-094198

(51) Int. Cl. H10D 1/68; H03H 7/01; H03H 7/38

(52) U.S. Cl. CPC H10D 1/692; H03H 7/0115; H03H 7/38

(57) ABSTRACT

A semiconductor device that includes: a substrate; an insulating layer on the substrate; a first electrode layer on the insulating layer; a dielectric film on the first electrode layer; a second electrode layer on the dielectric film; a moisture-resistant film covering the first electrode layer and the second electrode layer; a first outer electrode passing through the moisture-resistant film and connected to the first electrode layer; and a second outer electrode passing through the moisture-resistant film and connected to the second electrode layer. The first electrode layer and the second electrode layer each comprise Al or an Al alloy. The outer electrodes each include a seed layer formed of Cu/Ti, Cu/Cr, or Cu/nichrome and a plating layer on the seed layer. The seed layer has a horizontal crystal grain size of 500 nm or less, and the plating layer has a horizontal crystal grain size of 500 nm or less.

### CROSS REFERENCE TO RELATED APPLICATIONS

The present application is a continuation of International application No. PCT/JP2024/017953, filed May 15, 2024, which claims priority to Japanese Patent Application No. 2023-094198, filed Jun. 7, 2025, the entire contents of each of which are incorporated herein by reference.

### TECHNICAL FIELD

The present disclosure relates to a semiconductor device, a matching circuit, and a filter circuit.

### BACKGROUND ART

A semiconductor device shown in FIGS. 1 and 2 in Patent Document 1 includes a substrate and further includes an insulating layer, a first electrode layer, a dielectric layer, a second electrode layer, a moisture-resistant protective layer, and a resin protective layer that are sequentially formed on the substrate. Vias passing through the moisture-resistant protective layer, the resin protective layer, etc. are formed so as to partially expose the surfaces of the first and second electrode layers, and first and second outer electrodes each including a seed layer, a first plating layer, and a second plating layer are formed on the exposed surfaces.

Patent Document 2 describes a technique for forming a Ni layer having a uniform thickness on the surface of an Al electrode by an electroless plating method.

A semiconductor device disclosed in Patent Document 3 includes a substrate, a first electrode layer disposed on the substrate, a dielectric film disposed on the first electrode layer, a second electrode layer disposed on the dielectric film, a protective layer that covers the first electrode layer and the second electrode layer, and outer electrodes passing through the protective layer. The dielectric film is formed of silicon nitride, and the atomic concentration ratio of Si to the total amount of Si and N contained in the dielectric film is 43 atom % to 70 atom %.
Patent Document 1: International Publication No. 2021/166880
Patent Document 2: Japanese Unexamined Patent Application Publication No. 2008-28079
Patent Document 3: International Publication No. 2022/239722

### SUMMARY OF THE DISCLOSURE

In Patent Document 1, a semiconductor process is used, and Al is used for the electrode layers.

FIG. 1 is a schematic cross-sectional view when a plating layer is formed by electrolytic plating at a slow deposition rate and shows the state in the initial stage of electrolytic plating. FIG. 2 is a schematic cross-sectional view when the plating layer is formed by electrolytic plating at the slow deposition rate and shows the state after completion of the electrolytic plating.

As shown in FIG. 1, when a base 121 is an amorphous film such as a SiO₂ or SiN film, recrystallization of an Al layer 122 proceeds depending on the deposition temperature of Al and heat treatment of a dielectric layer (SiN film) and a resin protective layer (polyimide) on the Al layer 122. Therefore, the Al layer 122 becomes a polycrystalline film including randomly oriented crystals. The crystals grow such that, while the size in the film thickness direction is about 0.1 to about 2 μm, the size in the horizontal direction reaches several μm to about 10 μm.

In the cross-sectional views in FIG. 1 and other figures, vertical lines passing through layers are crystal grain boundaries.

As shown in FIG. 1, a seed layer 123 of an outer electrode formed on the Al layer 122 includes a Ti layer 123a and a Cu layer 123b formed generally by a sputtering method, and the Ti layer 123a and the Cu layer 123b grow continuously in conformity with the crystalline structure of the surface of the Al layer 122. Therefore, the horizontal crystal grain size of the Ti layer 123a and the horizontal crystal grain size of the Cu layer 123b are the same as that of the Al layer 122, i.e., several to 10 μm.

A plating layer 124 formed on the seed layer 123 is formed by electrolytic plating using Cu, Ni, Au, etc. In this case, when the deposition rate of the Ni plating film is sufficiently small, the Ni plating film grows preferentially from grain boundary regions of the seed layer 123, and the growth from surface regions other than the grain boundary regions is extremely slow (see FIG. 1). Therefore, as shown in FIG. 2, although the film growth from the grain boundary regions proceeds in the horizontal direction, the film growth does not proceed sufficiently in the film thickness direction until the entire surface is covered. Once the entire surface is covered, the degree of surface unevenness of the Ni plating layer 124b becomes small because the deposition rate is uniform over the entire surface. However, when the deposition rate is reduced, the cost increases.

FIG. 3 is a schematic cross-sectional view when a plating layer is formed by electrolytic plating at a fast deposition rate and shows the state in the initial stage of electrolytic plating. FIG. 4 is a schematic cross-sectional view when the plating layer is formed by electrolytic plating at the fast deposition rate and shows the state after completion of the electrolytic plating.

In contrast to the above case, when the deposition rate is high, the difference in growth rate during Ni plating between the grain boundary regions and the surface regions other than the grain boundary regions is small as shown in FIG. 3. In this case, the surface is not entirely covered by the films grown from the grain boundary regions as shown in FIG. 4, and protrusions are formed on the surface of the Ni plating layer 124b at the grain boundaries where the growth rate is high.

These protrusions cause the outer electrode to have a highly randomly textured appearance, so that other appearance defects (such as film delamination, dust, flaws, and pattern defects) on the outer electrode cannot be inspected using an automatic appearance inspection device. To perform inspection using the automatic appearance inspection device, it is necessary that the surface roughness Ra of the plating be 500 nm or less.

FIG. 5 is a plan view schematically showing the surface of the outer electrode formed by electrolytic plating at a fast deposition rate.

When the horizontal crystal grain size of the Al layer 122 is several to 10 μm, protrusions 126 are formed on the surface of the outer electrode so as to trace the edges of irregular regions shaped depending on the grain sizes of large crystals 125 of the Al layer 122 as shown in FIG. 5. The automatic appearance inspection device may falsely detect the pattern formed by the protrusions 126 as appearance defects.

In a Cu plating layer 124a, the unevenness formed on the surface of the Ni plating layer 124b is not formed on the surface irrespective of the deposition rate, as shown in FIGS. 1 to 4.

In the semiconductor device described in Patent Document 3 that can function as a capacitor, the above problem can occur when the outer electrodes are formed by Ni plating.

One problem described in Patent Document 2 is that, since the growth rate of Ni plating formed on the Al electrode varies depending on the crystal plane of the Al electrode, Ni growth becomes nonuniform when the crystals of the Al electrode are large, resulting in unevenness. Therefore, a layer (Al oxide layer) that breaks the continuity of the Al crystals is formed on the Al metal layer, and then a second Al metal layer is formed on the surface of the Al metal layer to reduce the size of the Al crystals. Therefore, even when a Ni layer does not grow directly on the surfaces of crystal grains on which the Ni layer does not grow easily, a Ni layer formed around these crystal grains grows in directions parallel to the surface of the Al electrode (lateral directions). In this case, the surfaces of the crystal grains on which the Ni layer does not grow easily are also covered with the Ni layer, allowing the Ni layer formed to be uniform (see FIG. 1 of Patent Document 2).

In Patent Document 2, since electroless plating is used, growth from grain boundaries does not occur. However, in this case also, the plating grows continuously in conformity with the crystals of the Al layer. Therefore, the degree of unevenness in the plating film is reduced by reducing the crystal grain size of the Al layer. One specific countermeasure is to form an Al oxide layer on the surface of the Al layer, but this causes an increase in the electrical resistance of the electrode. Therefore, although this semiconductor device can function as a heat sink, the device does not function as an electrode and is therefore not suitable for capacitors.

The present disclosure has been made to solve the foregoing problems, and it is an object to provide a semiconductor device that includes outer electrodes each having a flat plating surface and that can be inspected for appearance defects using an appearance inspection device and to provide a matching circuit and a filter circuit each including the semiconductor device.

The semiconductor device of the disclosure includes: a substrate; an insulating layer on the substrate; a first electrode layer on the insulating layer; a dielectric film on the first electrode layer; a second electrode layer on the dielectric film; a moisture-resistant film covering the first electrode layer and the second electrode layer; a first outer electrode passing through the moisture-resistant film and electrically connected to the first electrode layer; and a second outer electrode passing through the moisture-resistant film and electrically connected to the second electrode layer, wherein the first electrode layer and the second electrode layer each comprise Al or an Al alloy, wherein the first outer electrode and the second outer electrode each include a seed layer comprising Cu/Ti, Cu/Cr, or Cu/nichrome and a plating layer on the seed layer, wherein the seed layer has a horizontal crystal grain size of 500 nm or less, and wherein the plating layer has a horizontal crystal grain size of 500 nm or less.

The matching circuit of the disclosure includes the semiconductor device of the disclosure.

The filter circuit of the disclosure includes the semiconductor device of the disclosure.

The present disclosure can provide a semiconductor device that includes outer electrodes each having a flat plating surface and that can be inspected for appearance defects using an appearance inspection device and can also provide a matching circuit and a filter circuit each including the semiconductor device.

### BRIEF DESCRIPTION OF THE DRAWINGS

FIG. 1 is a schematic cross-sectional view when a plating layer is formed by electrolytic plating at a slow deposition rate and shows the state in the initial stage of electrolytic plating.

FIG. 2 is a schematic cross-sectional view when the plating layer is formed by electrolytic plating at the slow deposition rate and shows the state after completion of the electrolytic plating.

FIG. 3 is a schematic cross-sectional view when a plating layer is formed by electrolytic plating at a fast deposition rate and shows the state in the initial stage of electrolytic plating.

FIG. 4 is a schematic cross-sectional view when the plating layer is formed by electrolytic plating at the fast deposition rate and shows the state after completion of the electrolytic plating.

FIG. 5 is a plan view schematically showing the surface of an outer electrode formed by electrolytic plating at the fast deposition rate.

FIG. 6 is a cross-sectional view schematically showing an example of a capacitor according to a first embodiment of the disclosure.

FIG. 7 is a plan view schematically showing the example of the capacitor according to the first embodiment of the disclosure.

FIG. 8 is a cross-sectional view focusing on a first outer electrode-formed region of the capacitor shown in FIG. 6.

FIG. 9 is a cross-sectional view focusing on a second outer electrode-formed region of the capacitor shown in FIG. 6.

FIG. 10 is an enlarged plan view schematically showing the surface of an outer electrode of the capacitor shown in FIG. 7.

FIG. 11 is a cross-sectional view schematically showing an example of a capacitor according to a second embodiment of the disclosure, the cross-sectional view focusing on a first outer electrode-formed region.

FIG. 12 is a cross-sectional view schematically showing the example of the capacitor according to the second embodiment of the disclosure, the cross-sectional view focusing on a second outer electrode-formed region.

FIG. 13 is a cross-sectional view schematically showing an example of a capacitor according to a third embodiment of the disclosure, the cross-sectional view focusing on a first outer electrode-formed region.

FIG. 14 is a cross-sectional view schematically showing the example of the capacitor according to the third embodiment of the disclosure, the cross-sectional view focusing on a second outer electrode-formed region.

FIG. 15 is a cross-sectional view schematically showing an example of a capacitor according to a fourth embodiment of the disclosure, the cross-sectional view focusing on a first outer electrode-formed region.

FIG. 16 is a cross-sectional view schematically showing the example of the capacitor according to the fourth embodiment of the disclosure, the cross-sectional view focusing on a second outer electrode-formed region.

FIG. 17 is a plan view schematically showing an example of a partitioning layer shown in FIGS. 15 and 16.

FIG. 18 is a plan view schematically showing another example of the partitioning layer shown in FIGS. 15 and 16.

FIG. 19 is an illustration showing an example of a matching circuit including the semiconductor device of the disclosure.

FIG. 20 is an illustration showing an example a filter circuit including the semiconductor device of the disclosure.

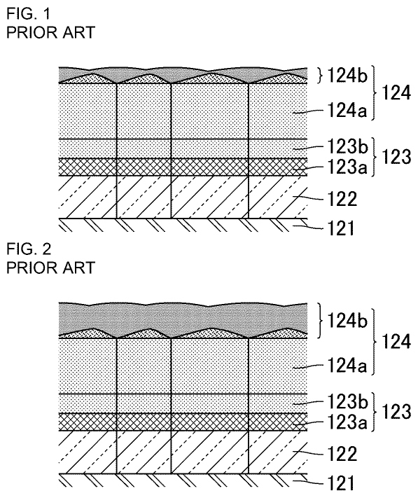

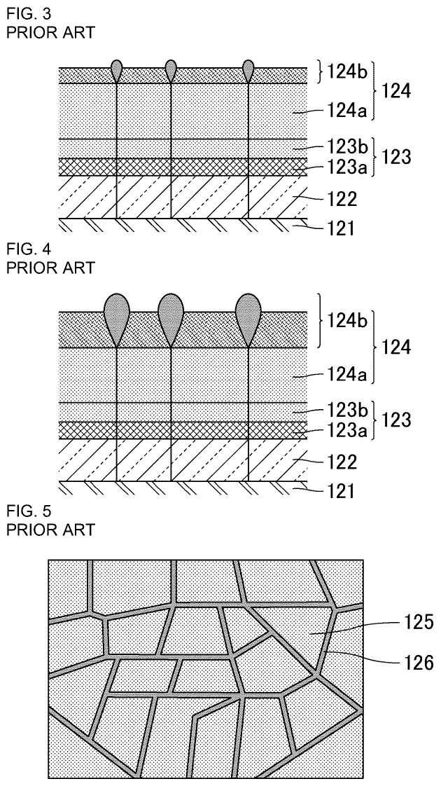

### DESCRIPTION OF THE PREFERRED EMBODIMENTS

The semiconductor device of the disclosure, the matching circuit of the disclosure, and the filter circuit of the disclosure will next be described.

However, the present disclosure is not limited to structures described below and may be embodied with various modifications without departing from the scope of the disclosure. The present disclosure also encompasses any combination of at least two preferred structures of the disclosure described below.

Embodiments described below are merely examples, and it will be appreciated that structures in one embodiment may be partially replaced or combined with structures in another embodiment. In second and subsequent embodiments, descriptions of features common to those of the first embodiment will be omitted, and only the differences will be described. In particular, similar operational advantages obtained in similar structures will not be described in all the embodiments.

In the following description, unless it is necessary to distinguish semiconductor devices in different embodiments from each other, they are collectively referred to as “the semiconductor device of the disclosure.” The shapes, arrangements, etc. of the structural components of the semiconductor device of the disclosure are not limited to those in the illustrated examples.

In the following description of embodiments of the semiconductor device of the disclosure, capacitors are used as examples. The semiconductor device of the disclosure may be a capacitor itself (i.e., a capacitor element) or may be a device including a capacitor.

### First Embodiment

In a capacitor according to a first embodiment of the disclosure, the surface roughness Ra of an insulating layer under a first electrode layer is controlled to be 5 nm to 500 nm.

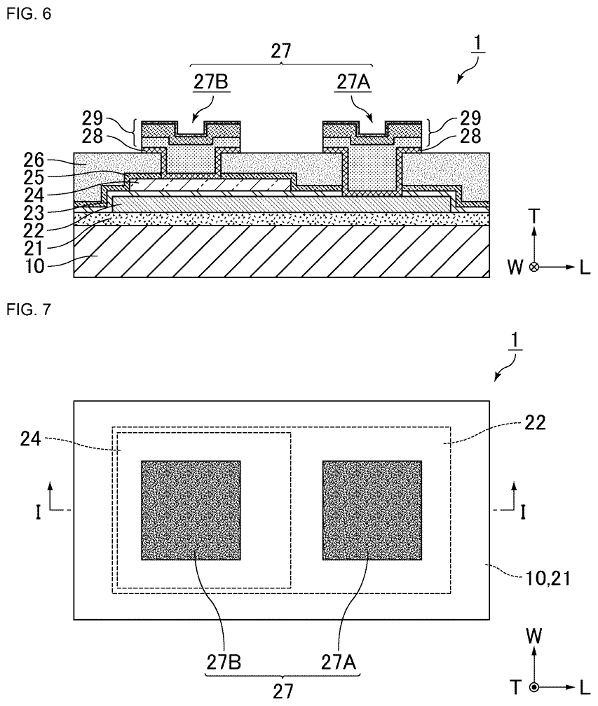

FIG. 6 is a cross-sectional view schematically showing an example of the capacitor according to the first embodiment of the disclosure. FIG. 7 is a plan view schematically showing the example of the capacitor according to the first embodiment of the disclosure. The cross-sectional view in FIG. 6 is taken along line I-I in the capacitor shown in FIG. 7.

In the present description, the length direction, the width direction, and the thickness direction of the capacitor (semiconductor device) are defined as the directions indicated by arrows L, W, and T, respectively, as shown in FIGS. 6 and 7 etc. The length direction L, the width direction W, and the thickness direction T are orthogonal to each other.

The capacitor 1 shown in FIGS. 6 and 7 includes: a substrate 10; an insulating layer 21 disposed on the substrate 10; a first electrode layer 22 disposed on the insulating layer 21; a dielectric film 23 disposed on the first electrode layer 22; a second electrode layer 24 disposed on the dielectric film 23; a moisture-resistant film 25 that covers the first electrode layer 22 and the second electrode layer 24; a protective layer 26 disposed on the moisture-resistant film 25; and outer electrodes 27 passing through the moisture-resistant film 25 and the protective layer 26. The first electrode layer 22 and the second electrode layer 24 are each formed of Al or an Al alloy. The outer electrodes 27 include a first outer electrode 27A connected to the first electrode layer 22 and a second outer electrode 27B connected to the second electrode layer 24. The first outer electrode 27A passes through the protective layer 26, the moisture-resistant film 25, and the dielectric film 23, and the second outer electrode 27B passes through the protective layer 26 and the moisture-resistant film 25. The outer electrodes 27 (the first outer electrode 27A and the second outer electrode 27B) each include a seed layer 28 formed of Cu/Ti, Cu/Cr, or Cu/nichrome and a plating layer 29 disposed on the seed layer 28.

In the capacitor 1, the first electrode layer 22, the dielectric film 23, and the second electrode layer 24 are stacked in this order and form an MIM (Metal Insulator Metal) capacitor structure. By applying a voltage between the first electrode layer 22 and the second electrode layer 24, electric charges can be accumulated in the dielectric film 23.

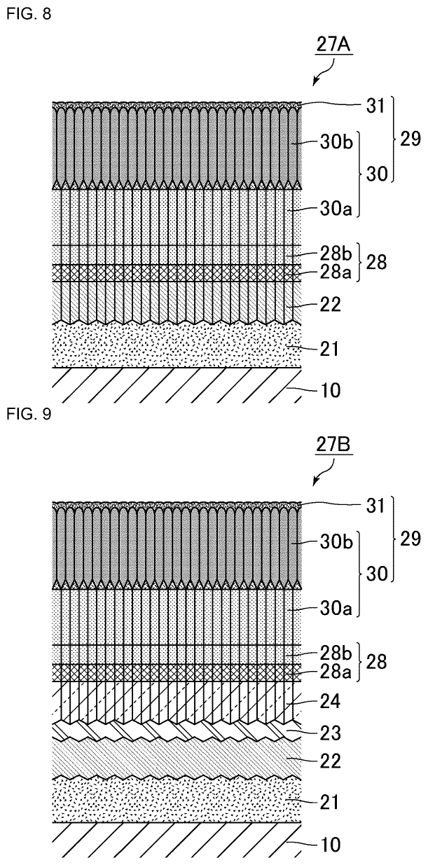

FIG. 8 is a cross-sectional view focusing on a first outer electrode-formed region of the capacitor shown in FIG. 6. FIG. 9 is a cross-sectional view focusing on a second outer electrode-formed region of the capacitor shown in FIG. 6.

As shown in FIGS. 8 and 9, the seed layer 28 has a horizontal crystal grain size of 500 nm or less, and the plating layer 29 has a horizontal crystal grain size of 500 nm or less. Therefore, the plating surface of the first outer electrode 27A and the plating surface of the second outer electrode 27B are flat. Specifically, the surface roughness Ra of the first outer electrode 27A and the surface roughness Ra of the second outer electrode 27B are each 500 nm or less. Generally, an appearance inspection device can detect defects of 0.5 to 1 μm or larger (such as film delamination, dust, flaws, and pattern defects). Therefore, the appearance inspection device can be used to inspect appearance defects of the capacitor 1, particularly on the outer electrodes 27.

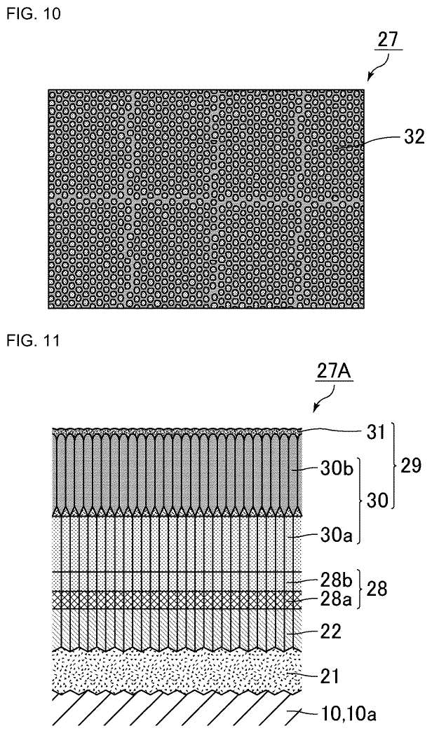

FIG. 10 is an enlarged plan view schematically showing the surface of one of the outer electrodes of the capacitor shown in FIG. 7.

When the horizontal crystal grain size of each of the seed layer 28 and the plating layer 29 is 500 nm or less, relief features with a size comparable to the grain size of small crystals 32 in the seed layer 28 and the plating layer 29 are formed regularly on the surfaces of the outer electrodes 27 as shown in FIG. 10. Since this fine relief pattern cannot be detected by the appearance inspection device, the surface relief of the outer electrodes 27 is not falsely detected as appearance defects.

However, when the horizontal crystal grain size of the seed layer 28 exceeds 500 nm and the horizontal crystal grain size of the plating layer 29 exceeds 500 nm, the appearance inspection device may falsely detect the relief features on the plating surfaces of the outer electrodes 27 as appearance defects.

The horizontal crystal grain size of the seed layer 28 is preferably 5 nm to 500 nm and more preferably 5 nm to 200 nm. The horizontal crystal grain size of the plating layer 29 is preferably 5 nm to 500 nm and more preferably 5 nm to 200 nm.

The horizontal crystal grain size is measured as follows. A cross section of the layer subjected to measurement is observed under a scanning electron microscope (SEM), and 50 crystal grains are randomly selected in the observation image. Then their grain sizes (maximum lengths) in in-plane directions (directions orthogonal to the thickness direction) are measured, and the average of the measured sizes is computed.

When the surfaces of the base layers for the first outer electrode 27A and the second outer electrode 27B formed of Al or an Al alloy are rough, the crystal grain sizes of the first outer electrode 27A and the second outer electrode 27B remain small during deposition and are unlikely to increase even during subsequent heat treatment. In this case, the seed layer 28 on the first outer electrode 27A and the second outer electrode 27B has a small horizontal crystal grain size, and the plating layer (preferably a Ni plating layer) on the seed layer 28 also has a small horizontal crystal grain size, as described above. Therefore, the relief features on the surfaces of the first outer electrode 27A and the second outer electrode 27B can be controlled to be small.

More specifically, in the present embodiment, the surface roughness Ra of the insulating layer 21 under the first electrode layer 22 is 5 nm to 500 nm, and the first electrode layer 22 and the second electrode layer 24 contain crystals grown according to the surface roughness of the insulating layer 21. The horizontal crystal grain sizes of the first electrode layer 22 and the second electrode layer 24 are 500 nm or less, and the seed layer 28 contains crystals grown in conformity with the crystals in the first electrode layer 22 and the second electrode layer 24. This allows the plating layer (preferably the Ni plating layer) grown in conformity with the crystals in the seed layer 28 to have a horizontal crystal grain size of 500 nm or less.

Specifically, on the first outer electrode 27A side, by controlling the surface roughness Ra of the insulating layer 21 under the first electrode layer 22 to be 5 nm to 500 nm, the horizontal crystal grain size of the first electrode layer 22 on the insulating layer 21 can be controlled to be 500 nm or less. Therefore, the horizontal crystal grain sizes of the seed layer 28 and the plating layer 29 in the first outer electrode 27A grown in conformity with the crystals in the first electrode layer 22 can be controlled to be 500 nm or less.

On the second outer electrode 27B side, by controlling the surface roughness Ra of the insulating layer 21 under the first electrode layer 22 to be 5 nm to 500 nm, the horizontal crystal grain size of the first electrode layer 22 on the insulating layer 21 can be controlled to be 500 nm or less, and the surface roughness of the dielectric film 23 on the first electrode layer 22 can also be controlled (controlled to be preferably 5 nm to 500 nm). In this case, the horizontal crystal grain size of the second electrode layer 24 on the dielectric film 23 can be controlled to be 500 nm or less. Therefore, the horizontal crystal grain sizes of the seed layer 28 and the plating layer 29 in the second electrode layer 24 grown in conformity with the crystals of the second electrode layer 24 can also be controlled to be 500 nm or less.

When the insulating layer 21 (formed of, for example, SiO₂) under the first electrode layer 22 is formed by a general deposition method such as thermal oxidation treatment of Si, sputtering, a CVD (chemical vapor deposition) method, or a vapor deposition method, the surface roughness Ra of the insulating layer 21 is less than 5 nm, and the surface is not roughened. If the surface roughness Ra of the insulating layer 21 is less than 5 nm, the crystals in the first electrode layer 22 and the second electrode layer 24 are not small in size. Therefore, the surface of the insulating layer 21 is subjected to grinding or polishing, to dry etching such as a reactive ion etching method (RIE) or a milling method, or to wet etching using hydrofluoric acid to adjust the surface roughness to a desired level.

In the present description, the surface roughness Ra is measured as the arithmetic mean roughness Ra measured according to JIS-B 0601:2001.

The surface roughness Ra of the insulating layer 21 is preferably 5 nm to 500 nm and more preferably 5 nm to 200 nm.

The period of the relief features on the surface of the insulating layer 21 is controlled to be preferably 20 nm to 500 nm and more preferably 20 nm to 200 nm.

The horizontal crystal grain sizes of the first electrode layer 22 and the second electrode layer 24 are preferably 5 nm to 500 nm and more preferably 5 nm to 200 nm.

The components will next be described in detail.

No particular limitation is imposed on the substrate 10. The substrate 10 is preferably a semiconductor substrate such as a silicon substrate or a gallium arsenide substrate.

The insulating layer 21 is disposed so as to entirely cover one of the principal surfaces of the substrate 10. The insulating layer 21 may be disposed so as to partially cover one of the principal surfaces of the substrate 10. However, it is necessary that the insulating layer 21 be larger than the first electrode layer 22 and be disposed in a region covering the entire first electrode layer 22.

No particular limitation is imposed on the material forming the insulating layer 21. Preferred examples of the material include SiO₂, SiN, Al₂O₃, HfO₂, Ta₂O₅, and ZrO₂. These materials are all amorphous.

The first electrode layer 22 is disposed so as to be spaced from the end portions of the substrate 10.

Specifically, the end portions of the first electrode layer 22 are located inward of the end portions of the substrate 10.

The first electrode layer 22 is formed of Al or an Al alloy. Examples of the Al alloy include AlSi.

The dielectric film 23 is disposed so as to cover the first electrode layer 22 except for an opening. In FIG. 6, the end portions of the dielectric film 23 are disposed also on surface portions of the insulating layer 21 that extend from the end portions of the first electrode layer 22 to the end portions of the substrate 10. It is not always necessary that the end portions of the dielectric film 23 extend to the end portions of the substrate 10.

No particular limitation is imposed on the material forming the dielectric film 23. Preferred examples of the material include oxides and nitrides such as SiO₂, SiN, Al₂O₃, HfO₂, and Ta₂O₅.

The second electrode layer 24 is disposed so as to face the first electrode layer 22 with the dielectric film 23 interposed therebetween.

The second electrode layer 24 is formed of Al or an Al alloy. Examples of the Al alloy include AlSi.

The moisture-resistant film 25 is disposed so as to cover the dielectric film 23 and the second electrode layer 24 except for openings. The moisture-resistant film 25 improves the moisture resistance of the capacitor element, particularly the dielectric film 23.

No particular limitation is imposed on the material forming the moisture-resistant film 25. Preferred examples of the material include moisture-resistant materials such as SiO₂ and SiN.

The protective layer 26 has an opening formed at a position corresponding to an opening passing through the dielectric film 23 and the moisture-resistant film 25 (an opening reaching the first electrode layer 22) and also has an opening at a position corresponding to an opening passing through the moisture-resistant film 25 (an opening reaching the second electrode layer 24). Since the protective layer 26 is provided, the capacitor element, particularly the dielectric film 23, is protected from moisture. It is not always necessary to provide the protective layer 26.

No particular limitation is imposed on the material forming the protective layer 26. Preferred examples of the material include resin materials such as polyimide resins and solder resist resins.

The outer electrodes 27 (the first outer electrode 27A and the second outer electrode 27B) have a multilayer structure and each include the seed layer 28 and the plating layer 29 arranged in this order from the substrate 10 side. Preferably, the outermost surfaces of the outer electrodes 27 are formed of Au or Sn.

The seed layer 28 is formed of Cu/Ti, Cu/Cr, or Cu/nichrome. This seed layer 28 can be grown continuously in conformity with the surface crystallinity of the first electrode layer 22 or the second electrode layer 24.

In the present description, the notation “element A/element B” refers to a multilayer body including an electroconductive layer formed of element B and an electroconductive layer formed of element A that are stacked in this order from the substrate side.

The seed layer 28 may be a multilayer body including a Ti layer 28a and a Cu layer 28b that are stacked in this order from the substrate 10 side, as shown in FIGS. 8 and 9.

A method for depositing the seed layer 28 is a sputtering or vapor deposition method. However, if the seed layer 28, e.g., the Cu/Ti layer, is deposited directly on the surface of an Al-made electrode layer (the first electrode layer 22 or the second electrode layer 24), the Q factor of the capacitor deteriorates due to the resistance of a natural oxide film on the surface of the Al electrode layer. Therefore, the surface of the Al electrode layer is subjected to dry etching such as milling in a vacuum immediately before the deposition of the seed layer 28, and then the seed layer 28 is successively deposited in a vacuum so that the influence of the natural oxide film on the surface of the Al electrode layer is eliminated. This allows the Al electrode layer and the seed layer 28 to be connected to each other with the resistance therebetween reduced. Moreover, since the seed layer 28 grows in conformity with the crystals on the surface of the Al electrode layer, the horizontal crystal grain size of the seed layer 28 can be controlled to be 500 nm or less. This is also the case when the seed layer 28 is deposited on an electrode layer formed of an Al alloy.

The plating layer 29 includes a first plating layer 30 and a second plating layer 31 that are arranged in this order from the substrate 10 side.

No particular limitation is imposed on the material of the first plating layer 30. However, it is preferable that the first plating layer 30 includes a Ni plating layer formed by Ni electrolytic plating. Protrusions are easily formed on the surface of the Ni plating layer when the deposition rate is increased, as described above. However, in the present embodiment, since the horizontal crystal grain size of the seed layer 28 is 500 nm or less, the crystal grain size of the Ni plating layer is also 500 nm or less even when the deposition rate is increased, and the size of relief features on the surface of the Ni plating layer can be effectively reduced.

The first plating layer 30 may have a single layer structure composed of the Ni plating layer or may have a layered structure including a Cu plating layer 30a and the Ni plating layer 30b that are stacked in this order from the substrate 10 side, as shown in FIGS. 8 and 9.

Examples of the material forming the second plating layer 31 include gold (Au) and tin (Sn).

More specifically, a Au/Ni/Cu layer or a Au/Ni layer may be deposited on the seed layer 28 by electrolytic plating. In this case, when the crystal grain size of a base electrode layer formed of Al or an Al alloy (the first electrode layer 22 or the second electrode layer 24) is large, the plating surface of the Cu or Ni layer serving as the first plating layer is roughened when the deposition rate is high. However, by controlling the crystal grain size of the base electrode layer to be small, the plating surface is not roughened even when the deposition rate is maximized, provided that the current density is less than or equal to the level at which the plating solution is not decomposed. This is because of the following reason. Since the crystal grain size of the seed layer 28 is sufficiently small, the plating film grown from the crystal grain boundaries of the seed layer 28 covers portions between the grain boundaries in an early stage. After the entire surface is covered with the plating film, the plating film grows at the same deposition rate over the entire surface. Similarly, the second plating layer and subsequent layers are not roughened.

The materials forming the first outer electrode 27A may be the same as or different from the materials forming the second outer electrode 27B.

The capacitor 1 shown in FIGS. 6 and 7 is produced, for example, a method described in Patent Document 3.

### Second Embodiment

A capacitor according to a second embodiment of the disclosure differs from the capacitor in the first embodiment in that the surface roughness Ra of a single crystal Si substrate is controlled to be 5 nm to 500 nm.

In the first embodiment, when the surface roughness of the insulating layer 21 is adjusted by, for example, etching, the film thickness of the insulating layer 21 becomes nonuniform. In this case, the parasitic capacitance through the semiconductor substrate becomes nonuniform, and this may cause deterioration of the capacitance accuracy of the capacitor 1.

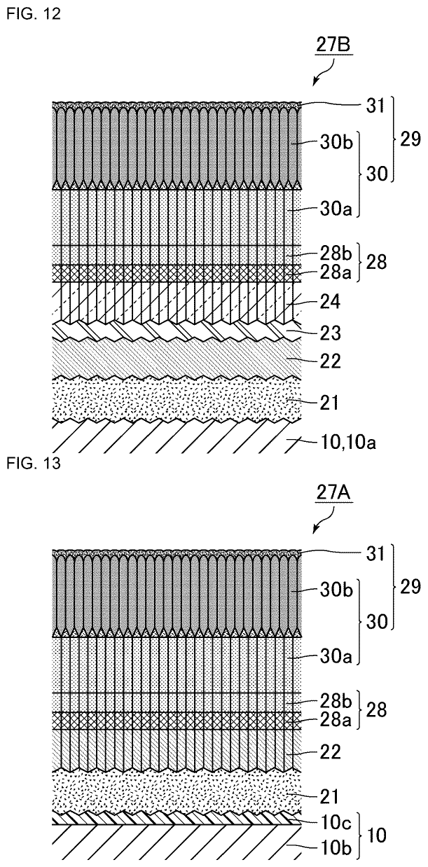

FIG. 11 is a cross-sectional view schematically showing an example of the capacitor according to the second embodiment of the disclosure, the cross-sectional view focusing on a first outer electrode-formed region. FIG. 12 is a cross-sectional view schematically showing the example of the capacitor according to the second embodiment of the disclosure, the cross-sectional view focusing on a second outer electrode-formed region.

In the present embodiment, the substrate 10 is a single crystal Si substrate 10a as shown in FIGS. 11 and 12. The surface roughness Ra of the single crystal Si substrate 10a is 5 nm to 500 nm, and the insulating layer 21 is formed along the surface of the single crystal Si substrate 10a. By roughening the surface of the single crystal Si substrate 10a under the insulating layer 21 and forming the insulating layer 21 along the surface of the single crystal Si substrate 10a as described above, the surface of the insulating layer 21 can be roughened without deterioration of the film thickness accuracy of the insulating layer 21. Therefore, the variations in the capacity of the capacitor due to the film thickness distribution of the insulating layer 21 can be reduced.

The single crystal Si substrate 10a can be roughened by grinding or polishing the flat surface of the single crystal Si substrate or by etching the flat surface using a dry etching method such as a reactive ion etching (RIE) or milling method or a wet etching method using an organic alkali solution, and the surface roughness can thereby be adjusted desirably. By controlling the surface roughness Ra of the single crystal Si substrate 10a to be 5 nm to 500 nm, the insulating layer 21 on the single crystal Si substrate 10a can also have the same surface roughness.

The surface roughness Ra of the single crystal Si substrate 10a is preferably 5 nm to 500 nm and more preferably 5 nm to 200 nm.

The period of the relief features on the surface of the single crystal Si substrate 10a is controlled to be preferably 20 nm to 500 nm and more preferably 20 nm to 200 nm.

### Third Embodiment

A capacitor according to a third embodiment of the disclosure differs from the capacitor in the first embodiment in that a polycrystalline Si layer having a surface roughness Ra controlled to 5 nm to 500 nm is formed on a single crystal Si substrate having a flat surface.

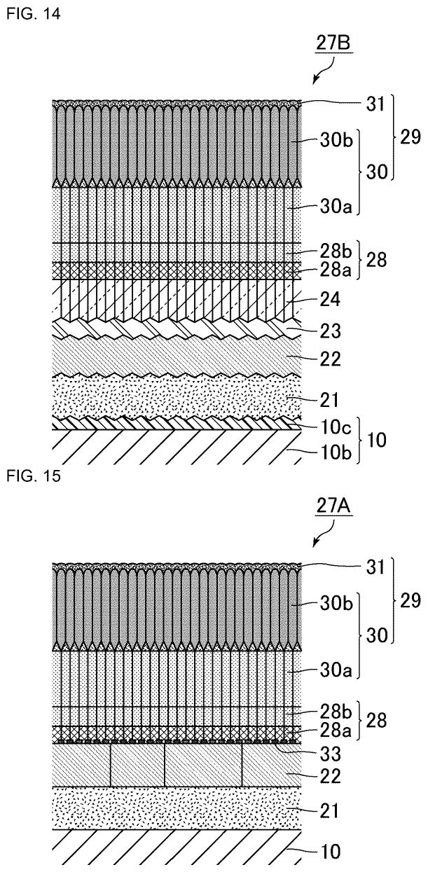

FIG. 13 is a cross-sectional view schematically showing an example of the capacitor according to the third embodiment of the disclosure, the cross-sectional view focusing on a first outer electrode-formed region. FIG. 14 is a cross-sectional view schematically showing the example of the capacitor according to the third embodiment of the disclosure, the cross-sectional view focusing on a second outer electrode-formed region.

In the present embodiment, the substrate 10 includes a single crystal Si substrate 10b having a flat surface and a polycrystalline Si layer 10c formed on the surface of the single crystal Si substrate 10b as shown in FIGS. 13 and 14, and the surface roughness Ra of the polycrystalline Si layer 10c is 5 nm to 500 nm. By forming the polycrystalline Si layer 10c with the controlled surface roughness Ra under the insulating layer 21 and forming the insulating layer 21 along the surface of the polycrystalline Si layer 10c, the surface of the insulating layer 21 can be roughened without deterioration of the film thickness accuracy of the insulating layer 21. Therefore, the variations in the capacity of the capacitor due to the film thickness distribution of the insulating layer 21 can be reduced.

When polycrystalline Si is used, the grain size of the polycrystal can be controlled with high accuracy. Therefore, the surface roughness Ra of the substrate 10 can be controlled more accurately (more homogeneously and more uniformly) than with a different method such as etching or grinding as used in the second embodiment.

The polycrystalline Si layer 10c is formed by depositing a Si polycrystalline film on the flat surface of the single crystal Si substrate 10b by, for example, a CVD method. By adjusting the deposition conditions, the thickness of the polycrystalline Si layer 10c, the degree of heating after the deposition, etc., the crystal grain size of the polycrystalline Si layer 10c can be easily and stably controlled, in contrast to the amorphous insulating layer 21 and the single crystal Si substrate 10b. Therefore, the surface roughness of the insulating layer 21 formed on the polycrystalline Si layer 10c can be easily controlled to the desired level. By controlling the surface roughness Ra of the polycrystalline Si layer 10c to be 5 nm to 500 nm, the insulating layer 21 on the polycrystalline Si layer 10c can also have the same surface roughness.

The surface roughness Ra of the polycrystalline Si layer 10c is preferably 5 nm to 500 nm and more preferably 5 nm to 200 nm.

The period of the relief features on the surface of the polycrystalline Si layer 10c is controlled to be preferably 20 nm to 500 nm and more preferably 20 nm to 200 nm.

In the present embodiment, no particular limitation is imposed on the surface roughness Ra of the single crystal Si substrate 10b. Generally, the single crystal Si substrate 10b is mirror-polished, and its surface roughness Ra is less than 5 nm.

### Fourth Embodiment

A capacitor according to a fourth embodiment of the disclosure differs from the capacitor in the first embodiment in that the capacitor further includes a partitioning layer on the surfaces of the first and second electrode layers. The partitioning layer is formed of a material that prevents the seed layer from growing in conformity with the crystals in the first and second electrode layers.

Generally, a natural Al or Al alloy oxide film is present on the surfaces of the first and second electrode layers. If the seed layer (e.g., the Cu/Ti layer) is formed directly on the natural oxide film, the natural oxide film serves as a high-resistance film, so that the Q factor of the capacitor deteriorates. However, if all the natural oxide film is removed, relief features are formed on the plating layer on the first and second electrode layers as described in the Technical Problem, and the appearance cannot be inspected using the appearance inspection device.

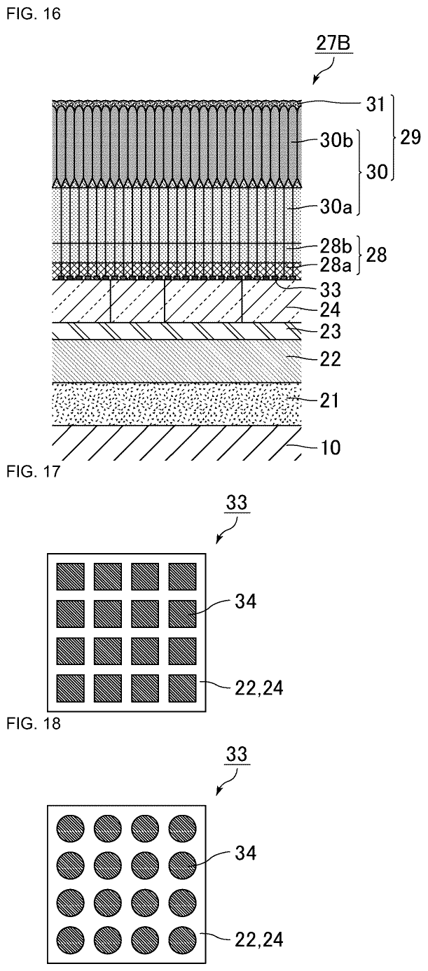

FIG. 15 is a cross-sectional view schematically showing an example of the capacitor according to the fourth embodiment of the disclosure, the cross-sectional view focusing on a first outer electrode-formed region. FIG. 16 is a cross-sectional view schematically showing the example of the capacitor according to the fourth embodiment of the disclosure, the cross-sectional view focusing on a second outer electrode-formed region.

In the present embodiment, the capacitor further includes the partitioning layer 33 that is disposed on the surfaces of the first electrode layer 22 and the second electrode layer 24 so as to form a pattern with a period of 500 nm or less, as shown in FIGS. 15 and 16. The partitioning layer 33 is formed of a material that prevents the seed layer 28 thereon from growing in conformity with the crystals in the first electrode layer 22 and the second electrode layer 24. In this manner, the horizontal crystal grain size of the seed layer 28 can be adjusted to 500 nm or less. Therefore, the appearance inspection device can be used to inspect appearance defects in the capacitor 1, particularly the outer electrodes 27.

A more detailed description will be given of the capacitor when the first electrode layer 22 and the second electrode layer 24 are formed of Al and the seed layer 28 is formed of Cu/Ti. The Cu/Ti layer grows on the oxide film on the Al electrode layers as uniaxially oriented crystals in which the (0001) of Ti and the (111) of Cu are perpendicular to a direction perpendicular to the film. In regions with the oxide film removed, the Cu/Ti layer grows as crystals grown in conformity with the random crystal orientations of the Al film. Therefore, by partially removing the oxide film on the surfaces of the first electrode layer 22 and the second electrode layer 24 at a period of 500 nm or less to thereby form the partitioning layer 33, the horizontal crystal grain size of the seed layer 28 can be adjusted to 500 nm or less.

The formation of the partitioning layer 33, i.e., the patterning of the oxide film on the first electrode layer 22 and the second electrode layer 24, can be performed, for example, as follows. First, a metal oxide film (such as an Al oxide film) is additionally formed on the surface of the natural oxide film (e.g., an Al oxide film) on the first electrode layer 22 and the second electrode layer 24, and then the resulting metal oxide film is patterned using photolithography and a dry etching method or a wet etching method. Then, immediately before the deposition of the seed layer 28 by sputtering, a portion corresponding to the thickness of a regrown natural oxide film is removed by a dry etching method, and then the seed layer 28 is deposited.

A material that can be used to form a film other than the Al oxide film on the surface of the natural oxide film (e.g., the Al oxide film) on the surfaces of the first electrode layer 22 and the second electrode layer 24 is Si, Ta, SiO₂, SiN, etc. With any of these materials, the electric resistance between the seed layer 28 and each of the first electrode layer 22 and the second electrode layer 24 can be reduced, and the horizontal crystal grain size of the plating layer 29 formed on the seed layer 28 can also be adjusted to 500 nm or less, so that the size of relief features on the surface can be reduced.

The period of the pattern of the partitioning layer 33 is preferably more than 0 nm and 500 nm or less and more preferably 20 nm to 200 nm.

FIG. 17 is a plan view schematically showing an example of the partitioning layer shown in FIGS. 15 and 16. FIG. 18 is a plan view schematically showing another example of the partitioning layer shown in FIGS. 15 and 16.

As shown in FIGS. 17 and 18, it is preferable that the partitioning layer 33 is formed into a two-dimensional pattern in which dots 34 having a quadrangular shape such as a rectangular shape or a circular shape are arranged periodically. In this case, the dots 34 are formed of a material that can form a pattern not in conformity with the crystals in the first electrode layer 22 and the second electrode layer 24, and the pitch between adjacent dots 34 is 500 nm or less. Preferably, the size of the dots 34 is substantially the same as the desired horizontal crystal grain size of the seed layer 28 and the plating layer 29. The exposed area of the first electrode layer 22 and the second electrode layer 24 (the area of regions uncovered with the partitioning layer 33 (dots 34)) is preferably 50% or more and more preferably 70% or more.

In FIGS. 17 and 18, all the dots 34 have the same planar shape. However, the pattern of the partitioning layer 33 may include dots with different planer shapes.

### [Evaluation Test]

Capacitors in the disclosure were actually produced, and an appearance inspection device was used to inspect defects (at 10 points) on the surface of each outer electrode. The results are shown in Table 1 below. In this test, AlSi layers were formed as the first and second electrode layers. A Cu/Ti layer was formed as the seed layer of each outer electrode, and a Au/Ni/Cu layer was formed as the plating layer of each outer electrode. The surface roughness of the insulating layer was changed to change the horizontal crystal grain size of the seed layer.

TABLE 1

| Grain size of base | Number of times relief features were |
|---|---|
| (nm) | detected as defects (out of 10) |
| 100 | 0 |
| 200 | 0 |
| 500 | 2 |
| 1000 | 10 |
| 10000 | 10 |

As can be seen from Table 1, when the horizontal crystal grain size of the seed layer serving as the base is 500 nm or less, the relief features on the surfaces of the outer electrodes caused by crystal grain boundaries can be substantially prevented from being detected as defects. This may be because the horizontal crystal grain size of the Ni plating layer, as well as that of the seed layer, was 500 nm or less. As can be seen, when the horizontal crystal grain size of the seed layer serving as the base is 200 nm or less, the relief features on the surfaces of the outer electrodes caused by crystal grain boundaries are not detected as defects. This may be because the horizontal crystal grain size of the Ni plating layer, as well as that of the seed layer, was 200 nm or less.

The semiconductor device of the disclosure is preferably used as a capacitor for a matching circuit or a filter circuit. The matching circuit or filter circuit including the semiconductor device of the disclosure is also included in the disclosure.

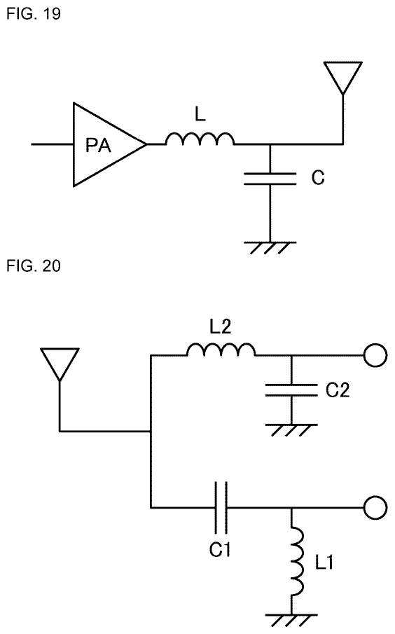

FIG. 19 is an illustration showing an example of the matching circuit including the semiconductor device of the disclosure.

For example, the semiconductor device of the disclosure can be used as a capacitor C in the matching circuit shown in FIG. 19.

FIG. 20 is an illustration showing an example of the filter circuit including the semiconductor device of the disclosure.

For example, the semiconductor device of the disclosure can be used as a capacitor C1 in the filter circuit shown in FIG. 20.

### REFERENCE SIGNS LIST

1 capacitor (semiconductor device)
10 substrate
10a, 10b single crystal Si substrate
10c polycrystalline Si layer
21 insulating layer
22 first electrode layer
23 dielectric film
24 second electrode layer
25 moisture-resistant film
26 protective layer
27 outer electrode
27A first outer electrode
27B second outer electrode
28 seed layer
28a Ti layer
28b Cu layer
29 plating layer
30 first plating layer
30a Cu plating layer
30b Ni plating layer
31 second plating layer
32 crystal
33 partitioning layer
34 dot

1. A semiconductor device comprising:
a substrate;
an insulating layer on the substrate;
a first electrode layer on the insulating layer;
a dielectric film on the first electrode layer;
a second electrode layer on the dielectric film;
a moisture-resistant film covering the first electrode layer and the second electrode layer;
a first outer electrode passing through the moisture-resistant film and electrically connected to the first electrode layer; and
a second outer electrode passing through the moisture-resistant film and electrically connected to the second electrode layer,
wherein the first electrode layer and the second electrode layer each comprise Al or an Al alloy,
wherein the first outer electrode and the second outer electrode each include a seed layer comprising Cu/Ti, Cu/Cr, or Cu/nichrome and a plating layer on the seed layer,
wherein the seed layer has a horizontal crystal grain size of 500 nm or less, and
wherein the plating layer has a horizontal crystal grain size of 500 nm or less.

2. The semiconductor device according to claim 1, wherein the horizontal crystal grain size of the seed layer is 5 nm to 200 nm.

3. The semiconductor device according to claim 1, wherein the horizontal crystal grain size of the plating layer is 5 nm to 200 nm.

4. The semiconductor device according to claim 1, wherein the insulating layer has a surface roughness Ra of 5 nm to 500 nm,
wherein the first electrode layer and the second electrode layer each have a horizontal crystal grain size of 500 nm or less, and
wherein the seed layer has a horizontal crystal grain size of 500 nm or less.

5. The semiconductor device according to claim 4, wherein the surface roughness Ra of the insulating layer is 5 nm to 200 nm.

6. The semiconductor device according to claim 1, wherein the horizontal crystal grain size of the first electrode layer and the second electrode layer is 5 nm to 200 nm.

7. The semiconductor device according to claim 4, wherein the substrate is a single crystal Si substrate,
wherein the single crystal Si substrate has a surface roughness Ra of 5 nm to 500 nm, and
wherein the insulating layer extends along a surface of the single crystal Si substrate.

8. The semiconductor device according to claim 1, wherein the substrate is a single crystal Si substrate,
wherein the single crystal Si substrate has a surface roughness Ra of 5 nm to 500 nm, and
wherein the insulating layer extends along a surface of the single crystal Si substrate.

9. The semiconductor device according to claim 8, wherein the surface roughness of the single crystal Si substrate is 5 nm to 200 nm.

10. The semiconductor device according to claim 4, wherein the substrate includes a single crystal Si substrate having a flat surface and a polycrystalline Si layer on the surface of the single crystal Si substrate, and
wherein the polycrystalline Si layer has a surface roughness Ra of 5 nm to 500 nm.

11. The semiconductor device according to claim 1, wherein the substrate includes a single crystal Si substrate having a flat surface and a polycrystalline Si layer on the surface of the single crystal Si substrate, and
wherein the polycrystalline Si layer has a surface roughness Ra of 5 nm to 500 nm.

12. The semiconductor device according to claim 11, wherein the surface roughness of the single crystal Si substrate is 5 nm to 200 nm.

13. The semiconductor device according to claim 1, further comprising a partitioning layer on a surface of the first electrode layer and a surface of the second electrode layer so as to form a pattern with a period of 500 nm or less, the partitioning layer comprising a material that prevents the seed layer on the partitioning layer from growing in conformity with crystals in the first electrode layer and the second electrode layer.

14. The semiconductor device according to claim 1, wherein the plating layer includes a first plating layer and a second plating layer.

15. The semiconductor device according to claim 12, wherein a crystal grain size of the first plating layer is 500 nm or less.

16. A matching circuit comprising the semiconductor device according to claim 1.

17. A filter circuit comprising the semiconductor device according to claim 1.
